(19) United States
(12) Patent Application Publication
(10) Pub. No.: US 2007/0205919 A1
(43) Pub. Date: Sep. 6, 2007

(54) Changeable panel structure

(75) Inventor: Yaz-Tzung Wu, Taipei (TW)

Correspondence Address: BIRCH STEWART KOLASCH & BIRCH, PO BOX 747, FALLS CHURCH, VA, 22040-0747, US

(73) Assignee: INVENTEC CORPORATION

(21) Appl. No.: 11/364,083

(22) Filed: Mar. 1, 2006

(51) Int. Cl. H03M 11/00

(52) U.S. Cl. 341/22

(57) ABSTRACT

A panel structure applicable to casing of a notebook computer has different cover plates to perform different input modules. The panel structure includes a base and a cover plate. The base is for settling a touch pad, a first group of keys and a second group of keys. The cover plate is formed with several openings for exposing a touch pad and a first group of keys. The cover plate is also formed with several removable portions that can be removed and formed with openings for exposing a second group of keys. The base adopts different cover plates formed with different openings. Therefore, the cost of preparing different bases can be saved. Further, different customer's choices can be easily satisfied by just selecting suitable cover plates. The assembly change is easily achieved.

### BACKGROUND OF THE INVENTION

1. Field of Invention

The invention generally relates to a panel structure, and in particular relates to a panel structure in which different cover plates are applicable to perform different input modules.

2. Related Art

Touch pads and track points are common input devices in notebook computers. They perform the same pointing and input functions of a mouse. Generally, there are keys located under the touch pad and track point to take the same functions of the left and right keys of a mouse. Notebook computers in the market can be categorized into commercial type and consumer type according to different user requirements. The commercial type may include all the touch pad, track point and related keys to meet the commercial user requirements. The consumer type only includes touch pad and keys for general requirements. To meet the two different requirements, the makers have to develop different toolings that increase the costs and also make the two types of components different and cannot be accommodated or interchanged for different customer's orders.

### SUMMARY OF THE INVENTION

The object of the invention is to provide a panel structure in which different cover plates are applicable to perform different input modules. The panel structure is a part of casing of a notebook computer. The panel structure includes a base and a cover plate. The base is for settling a touch pad, a first group of keys and a second group of keys. The cover plate is formed with several openings for exposing the touch pad and the first group of keys. The cover plate is also formed with several removable portions that can be removed and formed with openings for exposing the second group of keys. The base containing the touch pad, the first group of keys and/or the second group of keys can perform different panel combinations when being assembled with the cover plate on which the removable portions are selectively removed.

According to the invention, cover plates with different removable portions expose different input modules mounted on -the base. The base adopts different cover plates. Therefore, the cost of preparing different bases can be saved. Further, different customer's choices can be easily satisfied by just selecting suitable cover plates. The assembly change is easily achieved. The panel structure of the invention solves the problem of conventional structure. It saves the tooling cost, meets customer's different requirements and achieves easy change of assembly. It is practical and inventive.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given hereinbelow. However, this description is for purposes of illustration only, and thus is not limitative of the invention, wherein:

FIG. 1 is a structural descriptive view of the invention;

FIGS. 2A and 2B are descriptive views of a first embodiment of the invention;

FIGS. 3A, 3B and 3C are descriptive views of a second embodiment of the invention;

FIGS. 4A and 4B are descriptive views of a third embodiment of the invention; and

FIG. 5 is descriptive view of a fourth embodiment of the invention.

### DETAILED DESCRIPTION OF THE INVENTION

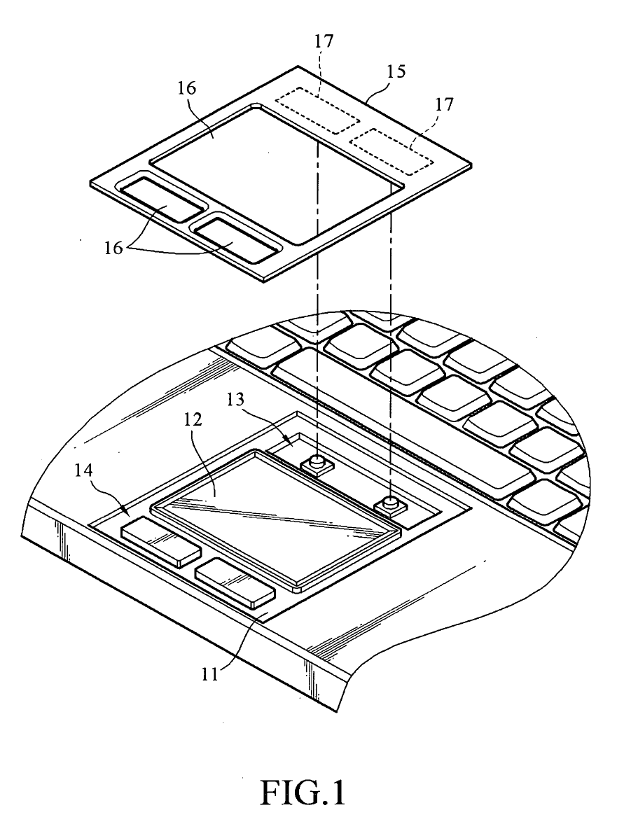

As shown in FIG. 1, a structural descriptive view of the invention, a panel structure includes a base 11 and a cover plate 15. The base 15 is for settling a touch pad 12, a first group of keys 14 and a second group of keys 13. The cover plate 11 is for covering the base 11 and formed with several openings 16 for exposing the touch pad 12 and the first group of keys 14. The cover plate 15 is also formed with several removable portions 17 that can be removed and formed with openings for exposing the second group of keys 13. The removable portions 17 have hidden semi-cutoffs under the top surface so as to be easily torn off.

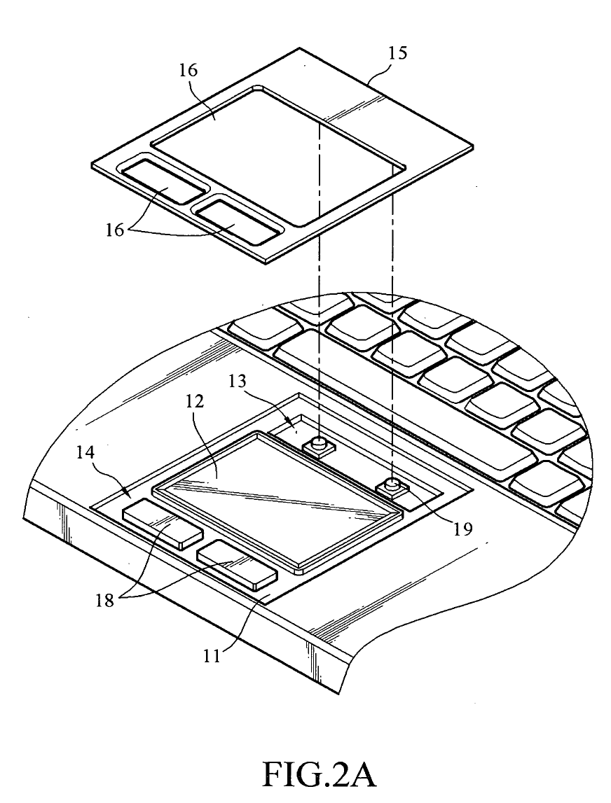

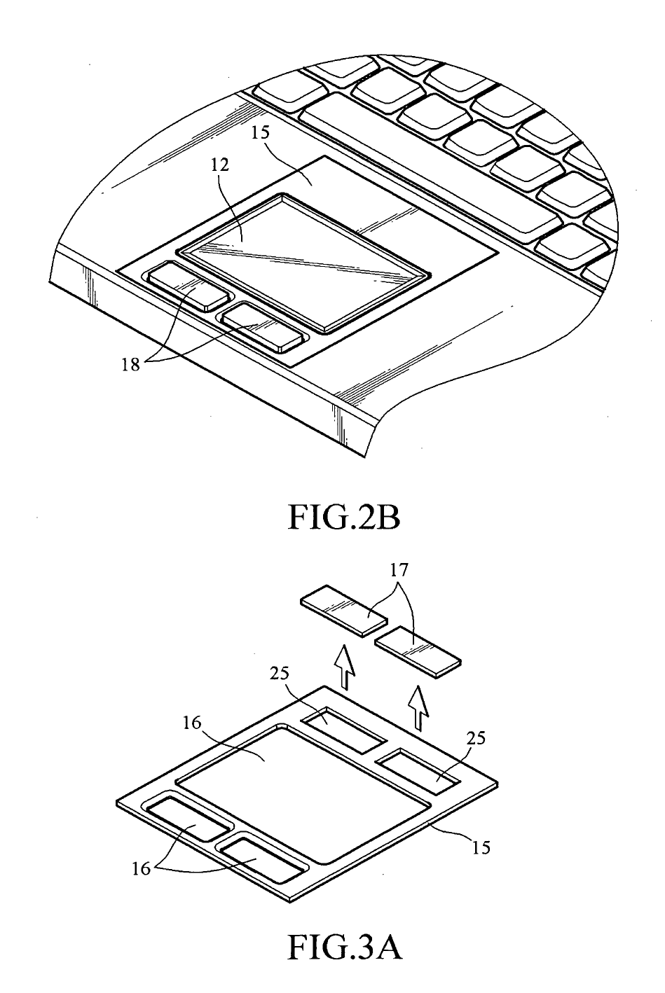

A first embodiment of the invention is illustrated in FIGS. 2A and 2B. As shown in the drawings, the first group of keys 14 has two keys 18 extruding from openings 16 of the cover plate 15 when the cover plate 15 being mounted on the base 11. (Of course it is not limited to the extruding keys 18 in other embodiments.) The keys 18 provide signals to the main unit (computer) when being pressed. The second group of keys 13 has two tact switches 19 (not shown in the drawing) located under the removable portions 17 of the cover plate 15 when the cover plate 15 being mounted on the base 11. (Of course it is not limited to the tact switches 19 in other embodiments.) The tact switches 19 provide signals to the main unit when being touched. As shown in FIG. 2A, the cover plate without removing the removable portion 17 is chosen to be mounted on the base 11 through adhesive (not shown) at its back. As shown in FIG. 2B, after assembling, the openings 16 expose the touch pad 12 and the extruding keys 18 so that the panel structure for the notebook computer includes input modules of touch pad 12 and first group of keys 14.

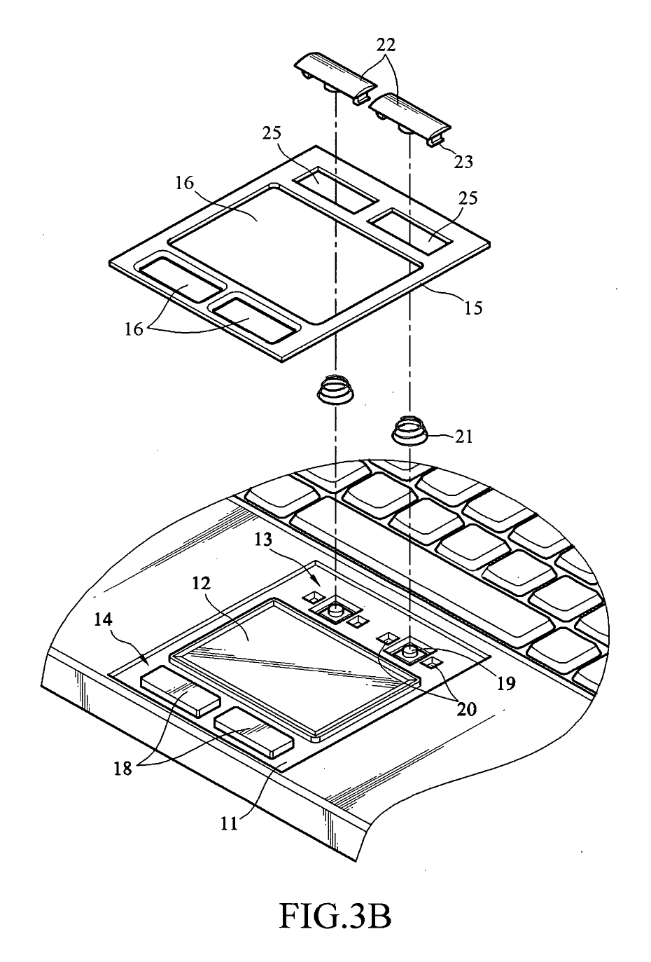

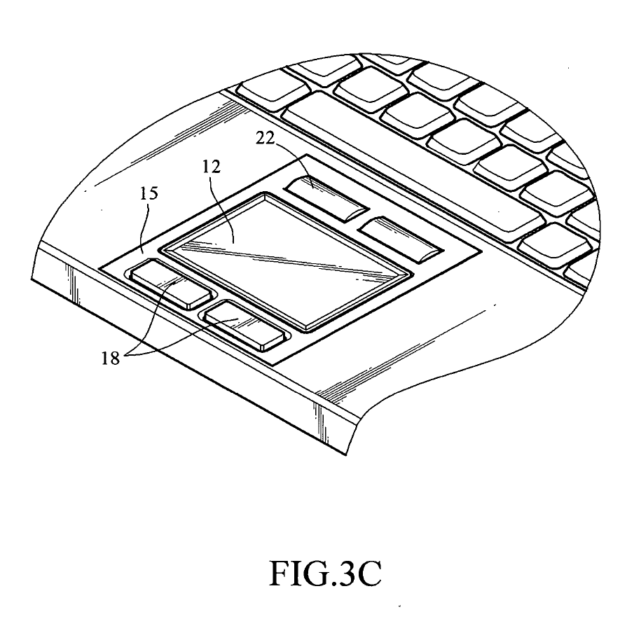

A second embodiment of the invention is illustrated in FIGS. 3A to 3C. As shown in FIG. 3A, there are two openings 25 formed on the cover plate 15 when two removable portions 17 being removed. (Of course it is not limited to two removable portions in other embodiments.) As shown in FIG. 3B, there are a spring 21 and two holes 20 arranged around each tact switch 19. The embodiment includes two keypads 22 each having two hooks 23. (Of course it is not limited to two keypads 22 in other embodiments.) The cover plate 15 having removable portion 17 removed is mounted on the base 11 through adhesive (not shown) at its back. The keypads 22 pass through the openings 25 to let the hooks latched through the holes 20 so that the keypads 22 pressing the tact switches 19 to generate signals to the main unit when being pressed by user. The springs 21 provide resilient force to lift the keypads 22 and to release the tact switches 19 when external force being removed. As shown in FIG. 3C, the openings 16 expose the touch pad 12 and the extruding keys 18; and the keypads 22 are installed on the cover plate 15. Therefore, after assembling, the panel structure for the notebook computer includes input modules of touch pad 12, first group of keys 14 and second group of keys 13. To increase the keys, it is only required to remove the removable portions and to add keypads. It is easy and no need to use a new tooling.

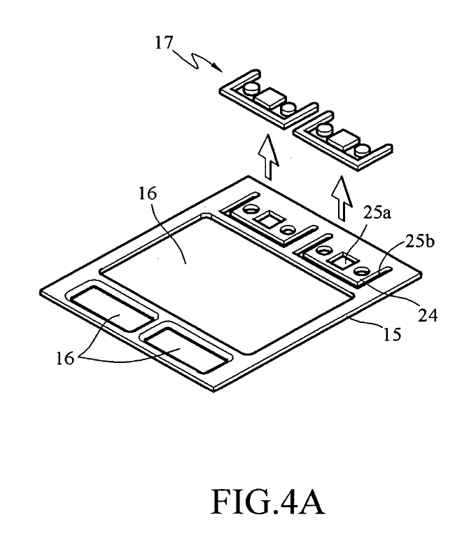

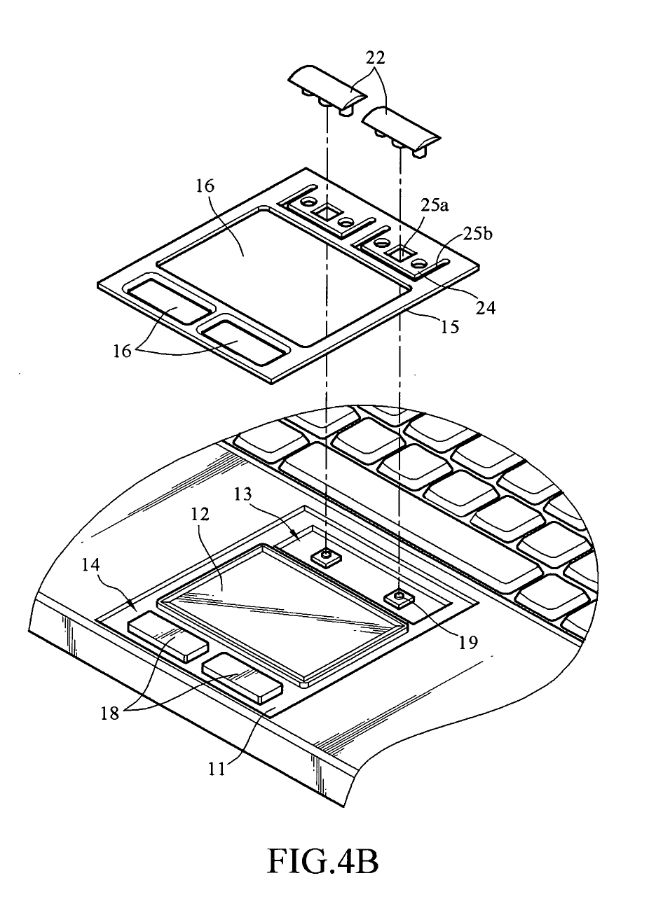

There are other methods to add keypads on the cover plate. For example, as shown in FIGS. 4A and 4B, which is a third embodiment of the invention, the removable portions 17 are removed to leave openings 25a, 25b on the cover plate 15. As shown in FIG. 4A, the opening 25b forms a resilient plate 24 (which is made of resilient plastic material). As shown in FIG. 4B, the keypads 22 pass the openings 25a and are adhered to the resilient plate 24 adhesive (not shown) at its back. Then, the cover plate 15 is adhered to the base 11. The keypads 22 passing through the openings 25a can press the tact switches 19 to generate signals to the main unit when being pressed by user. The resilient plate 24 provides resilient force to lift the keypads 22 and to release the tact switches 19 when external force being removed. The openings 16 expose the touch pad 12 and the extruding keys 18; and the keypads 22 are installed on the cover plate 15. Therefore, after assembling, the panel structure for the notebook computer includes input modules of touch pad 12, first group of keys 14 and second group of keys 13.

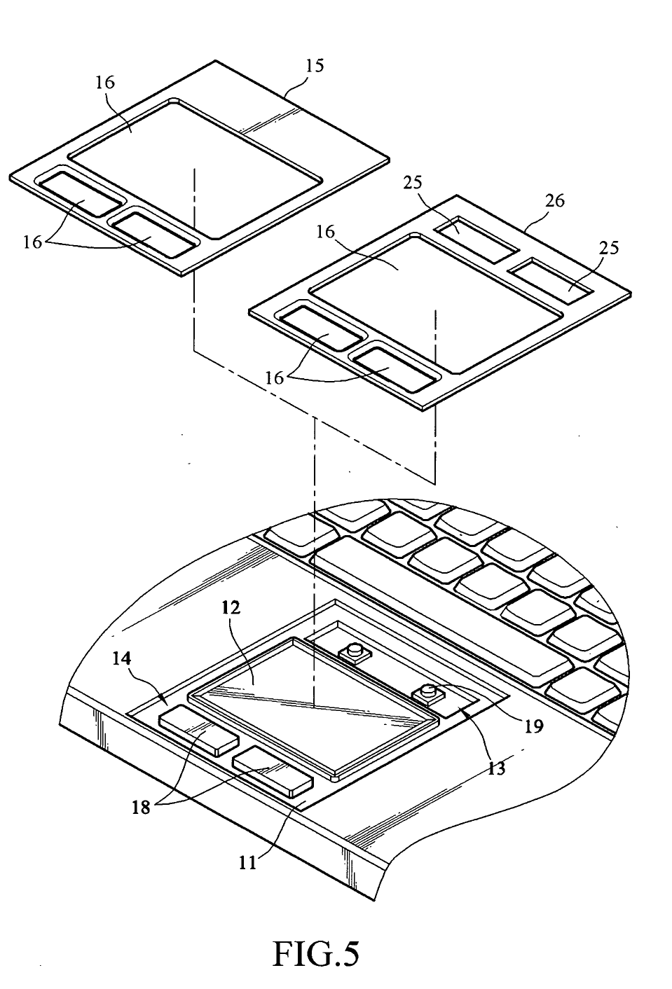

Further, different cover plates can be prepared for assemblies with the base and no need to form removable portions on the cover plate. As shown in FIG. 5, a fourth embodiment of the invention, there are two kinds of cover plate 15, 26 with different openings 16. When adhering the cover plate 15 on the base 11, there are touch pad and extruding keys exposed as shown in FIG. 2B. When adhering the cover plate 26 on the base 11 and adding keypads 22, there are touch pad, first group of keys and second group of keys exposed as shown in FIG. 3C.

In conclusion, the panel structure of the invention is a changeable structure that shares a same base. The base adopts different cover plates. Therefore, the cost of preparing different bases can be saved. Further, different customer's choices can be easily satisfied by just selecting suitable cover plates or removing some removable portions on a cover plate. The assembly change is easily achieved.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A panel structure having changeable cover plate and applicable to casing of a notebook computer, comprising:
a base, for containing a touch pad, a first group of keys and a second group of keys; and
a cover plate, for covering said base, formed with a plurality of openings for exposing said touch pad and said first group of keys; said cover plate is formed with a plurality of removable portions to be selectively removed and formed with openings for exposing said second group of keys.

2. The panel structure having changeable cover plate according to claim 1 wherein said first group of keys comprises a plurality of keys extruding from said opening of said cover plate when said cover plate being mounted on said base; said keys generate signals to said computer when being pressed.

3. The panel structure having changeable cover plate according to claim 1 wherein said second group of keys comprises a plurality of tact switches located under surface of said removable portions when said cover plate being mounted on said base; said tact switches generate signals to said computer when being touched.

4. The panel structure having changeable cover plate according to claim 3 further comprises a plurality of keypads to be installed in said openings formed on said cover plate when said removable portions being removed; said keypads touch said tact switches when being touched.

5. The panel structure having changeable cover plate according to claim 4 further comprises a resilient element located between said keypads and said second group of keys for retrieving relative positions of said keypads and said second group of keys when an external force being removed.

6. A panel structure having changeable cover plate and applicable to casing of a notebook computer, comprising:
a base, for containing a touch pad, a first group of keys and a second group of keys; and
at least two cover plates to be selectively chosen to cover said base; one of said cover plates is formed with a plurality of openings for exposing said touch pad and said first group of keys; another cover plate is formed with a plurality of openings for exposing said touch pad, said first group of keys and said second group of keys.

7. The panel structure having changeable cover plate according to claim 6 wherein said first group of keys comprises a plurality of keys extruding from said opening of said cover plate when said cover plate being mounted on said base; said keys generate signals to said computer when being pressed.

8. The panel structure having changeable cover plate according to claim 6 wherein said second group of keys comprises a plurality of tact switches located under surface of said openings when said cover plate being mounted on said base; said tact switches generate signals to said computer when being touched.

9. The panel structure having changeable cover plate according to claim 8 further comprises a plurality of keypads to be installed in said openings formed on said cover plate; said keypads touch said tact switches when being touched.

10. The panel structure having changeable cover plate according to claim 4 further comprises a resilient element located between said keypads and said second group of keys for retrieving relative positions of said keypads and said second group of keys when an external force being removed.
